(19) United States
(12) Patent Application Publication
(10) Pub. No.: US 2024/0105524 A1
(43) Pub. Date: Mar. 28, 2024

(54) OPTICAL DEVICE, DIE BONDING SYSTEM, AND DIE BONDING METHOD

(71) Applicant: SAMSUNG ELECTRONICS CO., LTD., Suwon-si (KR)

(72) Inventors: Hyungjin KIM, Suwon-si (KR); Minhwan SEO, Suwon-si (KR); Wondon JOO, Suwon-si (KR); Jiyoung CHU, Suwon-si (KR); Sangwoo BAE, Suwon-si (KR); Sungmin AHN, Suwon-si (KR); Seungyeol OH, Suwon-si (KR); Jungyu LEE, Suwon-si (KR)

(73) Assignee: SAMSUNG ELECTRONICS CO., LTD., Suwon-si (KR)

(21) Appl. No.: 18/367,229

(22) Filed: Sep. 12, 2023

(30) Foreign Application Priority Data
Sep. 23, 2022 (KR) 10-2022-0121012

(51) Int. Cl. H01L 21/66; G02B 5/30; G02B 27/09; G02B 27/28; H01L 21/68

(52) U.S. Cl. CPC H01L 22/12; G02B 5/3083; G02B 27/0955; G02B 27/0977; G02B 27/283; H01L 21/681

(57) ABSTRACT

The optical device includes an illuminator configured to emit illumination light in a first horizontal direction, a polarizing prism configured to polarize the illumination light incident thereto through a first surface thereof in the first horizontal direction, a first reflector and a second reflector, each configured to reflect the illumination light from the polarizing prism, and a first lens and a second lens configured to condense the illumination light reflected from the first and second reflectors, respectively.

### CROSS-REFERENCE TO RELATED APPLICATION

This application is based on and claims priority under 35 U.S.C. § 119 to Korean Patent Application No. 10-2022-0121012, filed on Sep. 23, 2022, in the Korean Intellectual Property Office, the disclosure of which is incorporated by reference herein in its entirety.

### BACKGROUND

The disclosure relates to an optical device, a die bonding system, and a die bonding method, and more particularly, to an optical device for checking alignment between a die and a wafer, a die bonding system, and a method of bonding a die to a wafer using the die bonding system.

In a manufacturing process that use die-to-wafer bonding for manufacturing products, such as double data rate (DDR) memory, high bandwidth memory (HBM), and complementary metal-oxide semiconductor (CMOS) image sensor (CIS), it is important to ensure bonding accuracy between a die and a wafer. To ensure the bonding accuracy, it is necessary to minimize sensitivity to environmental changes in an optical system for measuring the alignment between a die and a wafer.

### SUMMARY

Embodiments of the disclosure provide an optical device for decreasing light loss and decreasing alignment error between a die and a wafer, a die bonding system, and a die bonding method.

Embodiments of the disclosure are not limited to those described herein, and other embodiments that have not been explicitly mentioned will be clearly understood by one of skill in the art from the description below.

According to an aspect of the disclosure, there is provided an optical device including: a light source configured to emit light; a polarizing prism configured to polarize the light incident a first surface of the polarizing prism in a horizontal direction that is orthogonal to the first surface; a first reflector and a second reflector, each of the first reflector and the second reflector being configured to reflect the light output from the polarizing prism; a first lens configured to condense the light reflected by the first reflector; and a second lens configured to condense the light reflected by the second reflector.

The polarizing prism may include: a first prism, and a second prism adjacent to the first prism, and wherein the first prism and the second prism provide a splitter surface configured to split the light into first light and second light.

The first light may be reflected from the splitter surface, is totally reflected inside the first prism, and is output to the first reflector, and wherein the second light passes through the splitter surface, is totally reflected inside the second prism, and is output to the second reflector.

The polarizing prism may be further configured to linearly polarize the light incident on the polarizing prism in the horizontal direction.

The polarizing prism may be further configured to allow p-polarization to pass through a splitter surface of the polarizing prism and s-polarization to be reflected by the splitter surface.

The optical device may further include a first phase retarder adjacent to the first reflector, and a second phase retarder adjacent to the second reflector, wherein the light is incident on the first phase retarder and the second phase retarder.

Each of the first phase retarder and the second phase retarder may be configured to circularly polarize the light.

The optical device may further include a folding mirror unit configured to: radiate the light from the first lens to a first alignment mark, and radiate the light from the second lens to a second alignment mark, wherein the first alignment mark is spaced apart from and faces the second alignment mark in a vertical direction that is orthogonal to the horizontal direction.

The folding mirror unit may include: a first reflective surface configured to reflect first reflected light reflected from the first alignment mark, and a second reflective surface configured to reflect second reflected light reflected from the second alignment mark, and wherein the first reflected light and the second reflected light are output in opposite horizontal directions orthogonal to the vertical direction.

The optical device may further include a photodetector configured to detect the first reflected light and the second reflected light, each of the first reflected light and the second reflected light being output from a second surface of the polarizing prism.

According to another aspect of the disclosure, there is provided a die bonding system including: a first stage having a first adsorbing surface, the first stage being configured to adsorb a wafer on the first adsorbing surface; a second stage having a second adsorbing surface facing the first adsorbing surface in a vertical direction, the second stage being configured to adsorb a die on the second adsorbing surface; a first driver configured to move at least one of the first stage and the second stage; and an optical device configured to: simultaneously capture a first alignment mark of the wafer and a second alignment mark of the die, and detect information about a relative position between the first alignment mark and the second alignment mark, wherein the optical device includes: a light source configured to emit light; and a photodetector configured to detect reflected light generated when the light is reflected from the wafer and the die, wherein the optical device is further configured to polarize the light and the reflected light, and wherein the optical device is configured to be movable between the first stage and the second stage in a horizontal direction that is orthogonal to the vertical direction.

The optical device may further include a polarizing prism configured to linearly polarize the light incident on a first surface of the polarizing prism in the horizontal direction; and a first phase retarder and a second phase retarder, each of the first phase retarder and the second phase retarder being configured to polarize and retard the light or the reflected light reflected from one of the first alignment mark and the second alignment mark.

The reflected light may include first reflected light and second reflected light, wherein the first phase retarder may be configured to p-polarize the first reflected light reflected from the first alignment mark as p-polarized first reflected light, and wherein the second phase retarder may be configured to s-polarize the second reflected light reflected from the second alignment mark as s-polarized second reflected light.

The polarizing prism may be further configured to transmit the p-polarized first reflected light and reflect the s-polarized second reflected light.

First reflected light reflected from the first alignment mark may propagate along a first optical path of the optical device, second reflected light reflected from the second alignment mark may propagate along a second optical path of the optical device, and wherein a length of the first optical path is equal to a length of the second optical path.

The photodetector may be further configured to obtain a first image of the first alignment mark from the first reflected light reflected and a second image of the second alignment mark from the second reflected light reflected.

The optical device may further include a second driver configured to move the optical device to a measurement position between the first stage and the second stage or a standby position outside the first stage and the second stage.

According to another aspect of the disclosure, there is provided a die bonding system includes: a first stage having a first adsorbing surface, the first stage being configured to adsorb a wafer on the first adsorbing surface; a second stage having a second adsorbing surface facing the first adsorbing surface in a vertical direction, the second stage being configured to adsorb a die on the second adsorbing surface; a first driver configured to move at least one of the first stage and the second stage; and an optical device configured to: simultaneously capture a first alignment mark of the wafer and a second alignment mark of the die, and detect information about a relative position between the first alignment mark and the second alignment mark, wherein the optical device includes: a polarizing prism configured to split light into first light with s-polarization and second light with p-polarization, the light being incident on a first surface of the polarizing prism in a horizontal direction that is orthogonal to the vertical direction; and a first phase retarder and a second phase retarder, each configured to polarize and retard the light or reflected light reflected from one of the first alignment mark and the second alignment mark, and wherein the optical device is configured to be movable between the first stage and the second stage in the horizontal direction that is orthogonal to the vertical direction.

The first driver may be further configured to rotate or move at least one of the first stage and the second stage based on the information about the relative position.

The die bonding system may further include a second driver configured to move the optical device to a measurement position between the first stage and the second stage or a standby position outside the first stage and the second stage, wherein, after the at least one of the first stage and the second stage is moved by the first driver, the second driver is further configured to move the optical device from the measurement position to the standby position.

### BRIEF DESCRIPTION OF THE DRAWINGS

The above and/or other aspects will be more clearly understood from the following detailed description taken in conjunction with the accompanying drawings, in which:

FIG. 1 is a cross-sectional view of a die bonding system according to an example embodiment;

FIG. 2 is a schematic cross-sectional view of a die bonding system according to an example embodiment;

FIG. 3 is a plan view of an optical device for an alignment check, according to an example embodiment;

FIG. 4 is a partial enlarged view illustrating optical paths in the optical device of FIG. 3, according to an example embodiment;

FIG. 5 is a partial enlarged view illustrating optical paths in the optical device of FIG. 3, according to an example embodiment;

FIG. 6 is a perspective view of a portion of the optical device of FIG. 3, according to an example embodiment;

FIG. 7 is a flowchart of a die bonding method according to an example embodiment;

FIGS. 8 to 10 are cross-sectional views of stages in a die bonding method, according to an example embodiment;

FIGS. 11A, 11B and 11C are diagrams showing images with respect to a first alignment mark and a second alignment mark, according to an example embodiment; and

FIGS. 12 to 14 are cross-sectional views of stages in a die bonding method, according to an example embodiment.

### DETAILED DESCRIPTION

Hereinafter, embodiments are described in detail with reference to the accompanying drawings. In the drawing, like reference characters denote like elements, and redundant descriptions thereof will be omitted.

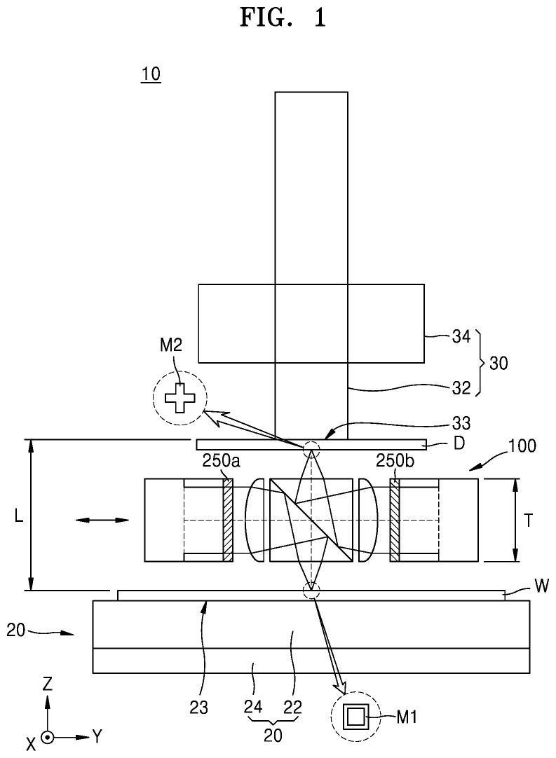

FIG. 1 is a cross-sectional view of a die bonding system according to an example embodiment.

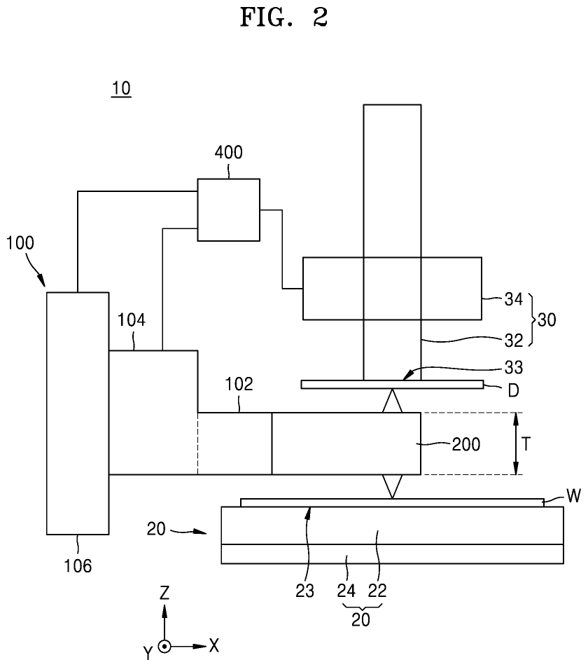

Referring to FIG. 1, a die bonding system 10 may include a lower support structure 20, an upper support structure 30, and an optical device 100 for an alignment check. The die bonding system 10 may further include a controller 400 as shown in FIG. 2 to control the operation of each of the lower support structure 20, the upper support structure 30, and the optical device 100 for an alignment check.

In detail, the lower support structure 20 may include a first stage 22. For example, the first stage 22 may be a platform or a structure to fix a wafer W. The first stage 22 may include a first adsorbing surface 23, on which the wafer W is positioned. According to an example embodiment, first decompression holes may be formed in the first adsorbing surface 23. The wafer W may be vacuum-adsorbed by the first decompression holes formed in the first stage 22.

According to an example embodiment, the upper support structure 30 may include a second stage 32. For example, the second stage 32 may be a platform or a structure to fix a die D. The second stage 32 may face the first stage 22. The first stage 22 and the second stage 32 may be parallel with each other in a vertical direction (e.g., the Z direction). The second stage 32 may include a second adsorbing surface 33, on which the die D is positioned. According to an example embodiment, an adsorbing structure like a collet may be formed on the second adsorbing surface 33. The die D may be vacuum-adsorbed by the adsorbing structure formed in the second stage 32.

Although the size of the die D with respect to the wafer W is relatively large in the drawings to describe a device and system of the inventive concept, the die D may be much smaller than the wafer W.

According to an example embodiment, the die bonding system 10 may be used to pick up the die D, which has been individualized by a sawing process, and bond the die D to a substrate, such as the wafer W or a printed circuit board (PCB). According to an example embodiment, the die bonding system 10 may be used to pick up a stack of dies. A bonding head driver 34 may adsorb the die D by using the upper support structure 30. The bonding head driver 34 may move the upper support structure 30 to bond the die D, which has been adsorbed to the upper support structure 30, to the wafer W. Here, a bonding head may refer to the upper support structure 30 for bonding the die D to the wafer W. For example, the bonding head driver 34 may move the upper support structure 30 in one of the X, Y, and Z directions.

According to an example embodiment, the bonding head driver 34 may move the upper support structure 30 in the Z direction. According to an example embodiment, a first stage driver 24 may move the first stage 22 in the X and Y directions or rotate the first stage 22. The die bonding system 10 may be used to bond the individualized die D to another die or bond a wafer to another wafer.

The wafer W and the die D may be fixed in various manners. For example, the wafer W may be vacuum-adsorbed by the decompression holes, and the die D may be vacuum-adsorbed by the adsorbing structure. According to another example embodiment, the wafer W and the die D may be adsorbed by using an electrostatic force like an electrostatic chuck or fixedly supported by a fixing tool, such as a clamper.

In detail, the upper support structure 30 may include the bonding head driver 34 moving the second stage 32. The bonding head driver 34 may include a linear driver, which linearly moves the second stage 32 in the X, Y, and Z directions, and a rotational driver, which rotates the second stage 32 around the Z axis. When the bonding head driver 34 linearly or rotationally moves the second stage 32, the relative position of the second stage 32 with respect to the first stage 22 may be adjusted.

The lower support structure 20 may include the first stage driver 24 moving the first stage 22. The first stage driver 24 may perform a similar function to the bonding head driver 34 on the first stage 22. For example, the first stage driver 24 may include a linear driver, which linearly moves the first stage 22 in the X, Y, and Z directions, and a rotational driver, which rotates the first stage 22 around the Z axis. When first stage driver 24 linearly or rotationally moves the first stage 22, the relative position of the first stage 22 with respect to the second stage 32 may be adjusted.

A distance L between the first and second stages 22 and 32 may be adjusted by one of the bonding head driver 34 and the first stage driver 24. As described below, when an image of an alignment mark for alignment between the first stage 22 and the second stage 32 is captured, the distance L between the first stage 22 and the second stage 32 may be maintained in a range of about 10 mm to about 20 mm.

According to an example embodiment, before bonding the die D to the wafer W, the optical device 100 for an alignment check may simultaneously capture a first alignment mark M1 on the wafer W and a second alignment mark M2 on the die D at a first image-capturing position. The optical device 100 for an alignment check may provide information about a relative position between the first alignment mark M1 and the second alignment mark M2 at the first image-capturing position. The optical device 100 for an alignment check may capture alignment marks at the first image-capturing position, move to a second image-capturing position, and perform an alignment check. The optical device 100 for an alignment check may perform alignment measurement at two or more image-capturing positions.

FIG. 2 is a schematic cross-sectional view of a die bonding system according to an example embodiment. FIG. 2 is described with reference to FIG. 1.

Referring to FIG. 2, the optical device 100 for an alignment check may correspond to an optical microscope and include a condensing optical system 102, a light-receiving optical system 104, and an optical head driver 106.

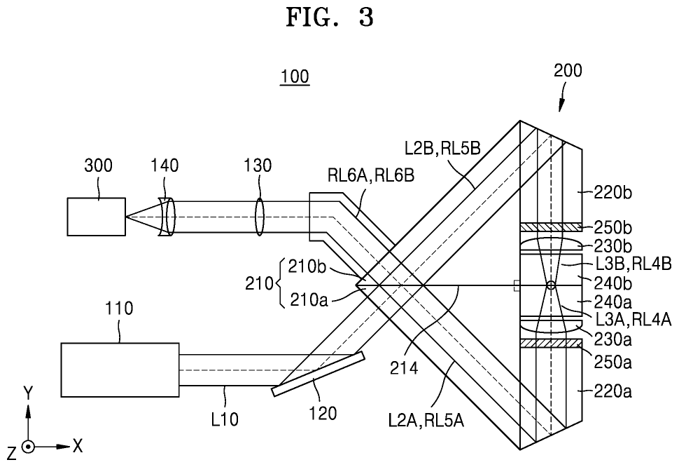

The condensing optical system 102 may split illumination light from a light source into first illumination light and second illumination light. The condensing optical system 102 may include an optical head 200, which is a part of an objective lens between the first alignment mark M1 and the second alignment mark M2, and a tube lens (140 in FIG. 3), which forms an image together with the objective lens. The optical head 200 is described in detail below with reference to FIGS. 3 to 6.

The light-receiving optical system 104 may detect first reflected light and second reflected light, which are output from the condensing optical system 102. For example, the first reflected light and second reflected light may be light that propagates through the condensing optical system 102. The light-receiving optical system 104 may include a photodetector 300 as shown in FIG. 3. The light-receiving optical system 104 may transmit information about the detected first reflected light and information about the detected second reflected light to a controller 400.

The optical head driver 106 may move the optical head 200 to a measurement position between the first and second stages 22 and 32 or an outer standby position. The optical head driver 106 may move the optical head 200 to the measurement position to simultaneously measure the first alignment mark M1 and the second alignment mark M2. After the first and second alignment marks M1 and M2 are captured, the optical head driver 106 may move the optical head 200 to the standby position to allow the die D to be bonded to the wafer W.

The optical head driver 106 may move the optical head 200 in the vertical direction (the Z direction) between the die D and the wafer W, which face each other. For example, a vertical width, i.e., a thickness T, of the optical head 200 may be about 5 mm to about 15 mm.

The controller 400 may calculate an alignment error between the die D and the wafer W, based on a relative position between the first alignment mark M1 and the second alignment mark M2, which is obtained from the optical device 100 for an alignment check. To remove the alignment error, the controller 400 may control the operation of at least one of the bonding head driver 34 and the first stage driver 24.

FIG. 3 is a plan view of the optical device 100 for an alignment check, according to an example embodiment.

Referring to FIG. 3, the optical device 100 for an alignment check may include an illuminator 110, a mirror 120, the optical head 200 for an alignment check, a third lens 130, a tube lens 140, and a photodetector 300.

The illuminator 110 may include a light source generating illumination light L10. For example, the illumination light L10 may be white light. However, the illumination light L10 is not limited to white light and may be monochromatic light having a particular wavelength. According to an example embodiment, the illuminator 110 may include a light guide unit, which guides illumination light generated by the light source, and a collimator lens, which converts divergent light output from the light guide unit into parallel light. According to an example embodiment, the light guide unit may be an optical fiber. However, the disclosure is not limited thererto, and as such, according to another example embodiment, the light guide unit may be implemented in a different manner.

The mirror 120 may be arranged to reflect the illumination light L10 to the optical head 200. For example, the mirror 120 may include a plane mirror. Accordingly, the illumination light L10 from the illuminator 110 may be incident to the optical head 200 in a first horizontal direction. Here, the first horizontal direction may refer to a direction extending from the illuminator 110 to the optical head 200 and include a direction existing on a plane defined by the X and Y axes.

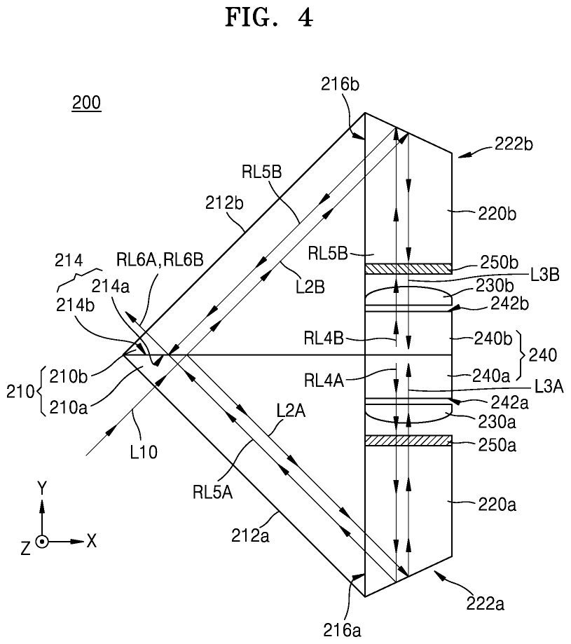

The optical head 200 may split the illumination light L10, which is incident in the first horizontal direction, into first illumination light L2A and second illumination light L2B. The optical head 200 may allow the first illumination light L2A and the second illumination light L2B to respectively illuminate the first alignment mark M1 and the second alignment mark M2, which are separated to face each other in the vertical direction (the Z direction). The optical head 200 may transmit first reflected light RL4A reflected from the first alignment mark M1 and second reflected light RL4B reflected from the second alignment mark M2. The optical head 200 and optical paths are described in detail below with reference to FIGS. 4 to 6.

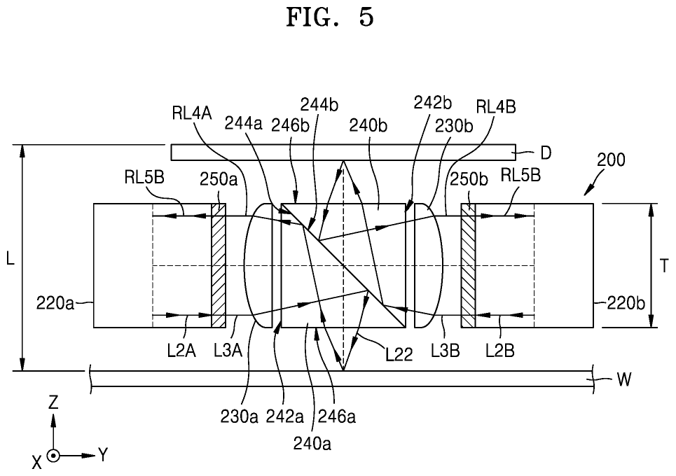

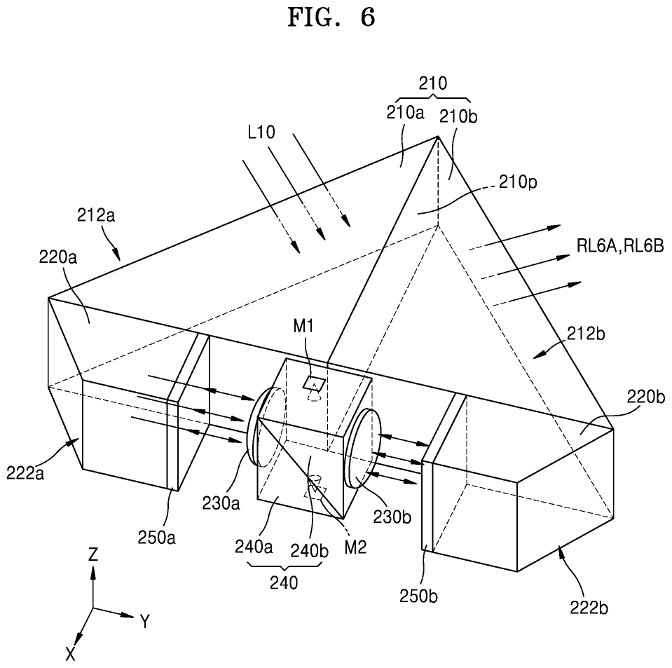

FIG. 4 is a partial enlarged view illustrating optical paths in the optical device 100 of FIG. 3, according to an example embodiment. FIG. 5 is a partial enlarged view illustrating optical paths in the optical device 100 of FIG. 3, according to an example embodiment. FIG. 6 is a perspective view of a portion of the optical device 100 of FIG. 3, according to an example embodiment.

Referring to FIGS. 4 and 6, the optical head 200 may include a polarizing prism 210, a first reflector 220a, a second reflector 220b, a first phase retarder 250a, a second phase retarder 250b, a first lens 230a, a second lens 230b, and a folding mirror unit 240.

The polarizing prism 210 may include a splitter surface 214, which splits the illumination light L10 incident on the splitter surface 214 into the first illumination light L2A and the second illumination light L2B. Here, the splitter surface 214 may include a polarizing splitter surface, which splits the illumination light L10 according to polarization. The splitter surface 214 may split the illumination light L10, which passes through the splitter surface 214, into s-polarization and p-polarization. Here, the first illumination light L2A may correspond to the illumination light L10 with s-polarization, and the second illumination light L2B may correspond to the illumination light L10 with p-polarization.

The polarizing prism 210 may include a beam splitting prism, in which a first prism 210a and a second prism 210b are joined together. Each of the first prism 210a and the second prism 210b may have edge angles of 30°, 45°, and 45°. Each of the first prism 210a and the second prism 210b may have an isosceles right triangle shape. The polarizing prism 210 may have an isosceles right triangle shape, in which the first prism 210a and the second prism 210b are joined together.

The first prism 210a may have a first side 212a facing a right angle, and a second side 214a and a third side 216a forming the right angle therebetween. The first side 212a may be referred to as a first surface. The second prism 210b may have a fourth side 212b facing a right angle, and a fifth sides 214b and sixth side and 216b forming the right angle therebetween. The fourth side 212b may be referred to as a second surface. Here, the second side 214a may be joined to the fifth side 214b, thereby providing the beam splitter surface 214. The second side 214a and the fifth side 214b may be parallel with a second horizontal direction (e.g., the X direction) that is orthogonal to the vertical direction (the Z direction).

The illumination light L10 may be incident to the first side 212a of the first prism 210a. The first side 212a of the first prism 210a may be used as an incident surface for the illumination light L10. The illumination light L10 may be incident to the first side 212a in the first horizontal direction that is orthogonal to the vertical direction (the Z direction) such that the optical axis of the illumination light L10 is orthogonal to the first side 212a.

The illumination light L10 incident in the first horizontal direction may be split by the beam splitter surface 214 into the first illumination light L2A and the second illumination light L2B. According to an example embodiment, the illumination light L10 incident in the first horizontal direction may have an incident angle of 45° on the beam splitter surface 214. However, the disclosure is not limited thereto, and as such, according to another example embodiment, the illumination light L10 may be incident on the beam splitter surface 214 at an angle different that 45°. Part of the illumination light L10 may be reflected from the second side 214a of the first prism 210a and become the first illumination light L2A with s-polarization, and the other part of the illumination light L10 may pass through the second side 214a of the first prism 210a and the fifth side 214b of the second prism 210b and become the second illumination light L2B with p-polarization.

The first illumination light L2A may be reflected inward from the first side 212a of the first prism 210a towards the third side 216a of the first prism 210a, and may be output from the third side 216a of the first prism 210a. For example, the first illumination light L2A reflected inward from the first side 212a of the first prism 210a may exit the first prism 210a through the third side 216a of the first prism 210a. The first illumination light L2A may be output from the third side 216a in a direction that is parallel with the second horizontal direction (the X direction) orthogonal to the vertical direction (the Z direction).

According to an example embodiment, terms including ordinal numbers, such as “first,” “second,” etc., have been used to describe various elements, but the elements are not limited by these terms. These terms are used only to distinguish one element from another. Accordingly, for example, the “first horizontal direction” is used to be distinguished from the “second horizontal direction” and may be referred to as a third horizontal direction or a fourth horizontal direction to be distinguished from a particular direction.

The second illumination light L2B may be propagated inward from the fourth side 212b of the second prism 210b and may be output from the sixth side 216b of the second prism 210b. For example, the second illumination light L2B may travel towards the sixth side 216b of the second prism 210b, and may exit the second prism 210b through the sixth side 216b of the second prism 210b. The second illumination light L2B may be output from the sixth side 216b in a direction that is parallel with the second horizontal direction (the X direction).

The first reflector 220a may include a right-angle prism. The first reflector 220a may include a first reflective surface 222a, which reflects the first illumination light L2A from the first prism 210a of the polarizing prism 210 to a first vertical surface 242a of the folding mirror unit 240. The first reflector 220a may reflect the first illumination light L2A in a direction that is parallel with a third horizontal direction (e.g., the Y direction) orthogonal to the vertical direction (the Z direction) and the second horizontal direction (the X direction).

For example, the right-angle prism may include a 45° prism. According to another example embodiment, the first reflector 220a may include a reflective mirror. According to an example embodiment, when the first or second horizontal direction is not labeled or provided, the third horizontal direction may be referred to as the first horizontal direction or second horizontal direction.

The second reflector 220b may include a right-angle prism. The second reflector 220b may include a second reflective surface 222b, which reflects the second illumination light L2B from the second prism 210b of the polarizing prism 210 to a second vertical surface 242b of the folding mirror unit 240. The second reflector 220b may reflect the second illumination light L2B in a direction that is parallel with the third horizontal direction (the Y direction) orthogonal to the vertical direction (the Z direction) and the second horizontal direction (the X direction). For example, the right-angle prism may include a 45° prism. According to another example embodiment, the second reflector 220b may include a reflective mirror.

The optical axis of the first illumination light L2A reflected by the first reflector 220a and the optical axis of the second illumination light L2B reflected by the second reflector 220b may be on the same line in the third horizontal direction (the Y direction).

The first phase retarder 250a may be provided between the first reflector 220a and the first lens 230a. The first phase retarder 250a may be adjacent to a side of the first reflector 220a. The second phase retarder 250b may be provided between the second reflector 220b and the second lens 230b. The second phase retarder 250b may be adjacent to a side of the second reflector 220b.

The first phase retarder 250a may circularly polarize the first illumination light L2A that has been reflected by the first reflector 220a. In other words, the first illumination light L2A before passing through the first phase retarder 250a may be in an s-polarization state, and a first illumination light L3A after passing through the first phase retarder 250a may be in a once circularly polarized state.

The second phase retarder 250b may circularly polarize the second illumination light L2B that has been reflected by the second reflector 220b. A second illumination light L3B after passing through the second phase retarder 250b may be in a once circularly polarized state. In other words, the second illumination light L2B before passing through the second phase retarder 250b may be in a p-polarization state, and a first illumination light L3B after passing through the second phase retarder 250b may be in a once circularly polarized state.

The first lens 230a may be between the first phase retarder 250a and the folding mirror unit 240. The first lens 230a may be in the optical path of the first illumination light L3A and may function as a focusing lens, which focuses the first illumination light L3A on the first alignment mark M1 on the wafer W.

The second lens 230b may be between the second phase retarder 250b and the folding mirror unit 240. The second lens 230b may be in the optical path of the second illumination light L3B and may function as a focusing lens, which focuses the second illumination light L3B on the second alignment mark M2 on the die D.

Referring to FIG. 5, the folding mirror unit 240 may include a first reflective surface 244a, which reflects vertically downwards the first illumination light L3A incident through the first vertical surface 242a, and a second reflective surface 244b, which reflects vertically upwards the second illumination light L3B incident through the second vertical surface 242b opposite the first vertical surface 242a. For example, the folding mirror unit 240 may include a mirror prism, in which a first right-angle prism 240a is joined to a second right-angle prism 240b. Each of the first right-angle prism 240a and the second right-angle prism 240b may include a 45° prism. Alternatively, the folding mirror unit 240 may include a reflective mirror having the first and second reflective surfaces 244a and 244b opposite each other.

The first reflective surface 244a of the first right-angle prism 240a may reflect the first illumination light L3A, which is incident through the first vertical surface 242a of the first right-angle prism 240a, vertically downwards, and the first illumination light L3A reflected from the first reflective surface 244a may exit through a first horizontal surface 246a of the first right-angle prism 240a. The first illumination light L3A that has been output through the first horizontal surface 246a of the first right-angle prism 240a may be focused on the first alignment mark M1 on the wafer W.

The second reflective surface 244b of the second right-angle prism 240b may reflect the second illumination light L3B, which is incident through the second vertical surface 242b of the second right-angle prism 240b, vertically upwards, and the second illumination light L3B reflected from the second reflective surface 244b may exit through a second horizontal surface 246b of the second right-angle prism 240b. The second illumination light L3B that has been output through the second horizontal surface 246b of the second right-angle prism 240b may be focused on the second alignment mark M2 on the die D.

The optical axis of the first illumination light L3A output through the first horizontal surface 246a of the first right-angle prism 240a and the optical axis of the second illumination light L3B output through the second horizontal surface 246b of the second right-angle prism 240b may be on the same line in the vertical direction (the Z direction) or parallel with the vertical direction (the Z direction).

The first illumination light L2A and L3A, which passes through the first prism 210a of the polarizing prism 210, the first reflector 220a, the first lens 230a, and the folding mirror unit 240 and illuminates the wafer W, may have a first optical path. The second illumination light L2B and L3B, which passes through the second prism 210b of the polarizing prism 210, the second reflector 220b, the second lens 230b, and the folding mirror unit 240 and illuminates the die D, may have a second optical path. At this time, the first optical path may have the same length as the second optical path.

The first illumination light L3A radiated to the first alignment mark M1 on the wafer W may be reflected and diffracted by the first alignment mark M1, and the second illumination light L3B radiated to the second alignment mark M2 on the die D may be reflected and diffracted by the second alignment mark M2. For example, the first illumination light L3A may be output on the first alignment mark M1 on the wafer W, and the first illumination light L3A may be reflected and diffracted by the first alignment mark M1. Further, the second illumination light L3B may be output on the second alignment mark M2 on the die D, and the second illumination light L3B may be reflected and diffracted by the second alignment mark M2. The first reflected light RL4A reflected by the first alignment mark M1 and the second reflected light RL4B reflected by the second alignment mark M2 may pass through the optical head 200 as the objective lens and the tube lens 140 and may be detected by the photodetector 300.

The first and second reflective surfaces 244a and 244b of the folding mirror unit 240 may respectively reflect the first reflected light RL4A from the first alignment mark M1 and the second reflected light RL4B from the second alignment mark M2 in different horizontal directions that are orthogonal to the vertical direction (the Z direction).

In detail, the first reflected light RL4A reflected by the first alignment mark M1 on the wafer W may be incident to the first horizontal surface 246a of the first right-angle prism 240a of the folding mirror unit 240. The first reflective surface 244a of the first right-angle prism 240a may reflect the first reflected light RL4A, which has been incident through the first horizontal surface 246a, in a direction that is parallel with the third horizontal direction (the Y direction), and the reflected first reflected light RL4A may be output through the first vertical surface 242a.

The second reflected light RL4B reflected by the second alignment mark M2 on the die D may be incident to the second horizontal surface 246b of the second right-angle prism 240b of the folding mirror unit 240. The second reflective surface 244b of the second right-angle prism 240b may reflect the second reflected light RL4B, which has been incident through the second horizontal surface 246b, in a direction that is parallel with the third horizontal direction (the Y direction), and the reflected second reflected light RL4B may be output through the second vertical surface 242b. The first reflected light RL4A and the second reflected light RL4B, which are respectively output through the first and second vertical surfaces 242a and 242b of the folding mirror unit 240, may respectively travel in opposite directions that are parallel with the third horizontal direction (the Y direction).

The first reflected light RL4A output through the first vertical surface 242a of the folding mirror unit 240 may pass through the first lens 230a. The first reflected light RL4A that has passed through the first lens 230a may be converted into parallel light.

The first reflected light RL4A output from the first lens 230a may pass through the first phase retarder 250a. Here, the first phase retarder 250a may linearly polarize the first reflected light RL4A. The first reflected light RL4A in a once circularly polarized state may be linearly polarized by the first phase retarder 250a to be in a p-polarization state. First reflected light RL5A after passing through the first phase retarder 250a may be in a p-polarization state.

The second reflected light RL4B output through the second vertical surface 242b of the folding mirror unit 240 may pass through the second lens 230b. The second reflected light RL4B that has passed through the second lens 230b may be converted into parallel light.

The second reflected light RL4B output from the second lens 230b may pass through the second phase retarder 250b. Here, the second phase retarder 250b may linearly polarize the second reflected light RL4B. The second reflected light RL4B in a once circularly polarized state may be linearly polarized by the second phase retarder 250b. Second reflected light RL5B after passing through the second phase retarder 250b may be in an s-polarization state. The second reflected light RL4B before passing through the second phase retarder 250b may be in a circularly polarized state, and the second reflected light RL5B after passing through the second phase retarder 250b may be in an s-polarization state.

The first reflected light RL5A may be in a p-polarization state and may be reflected by the first reflector 220a to be incident to the third side 216a of the polarizing prism 210. The first reflector 220a may reflect the first reflected light RL5A to the third side 216a of the first prism 210a in a direction that is parallel with the second horizontal direction (the X direction).

The second reflected light RL5B may be in an s-polarization state, and may be reflected by the second reflector 220b to be incident to the sixth side 216b of the polarizing prism 210. The second reflector 220b may reflect the second reflected light RL5B to the sixth side 216b of the second prism 210b in a direction that is parallel with the second horizontal direction (the X direction).

The first reflected light RL5A may be reflected inward from the first side 212a of the first prism 210a. The first reflected light RL5A reflected from the first side 212a of the first prism 210a may pass through the beam splitter surface 214. In detail, the first reflected light RL5A may pass through the second side 214a of the first prism 210a and the fifth side 214b of the second prism 210b. Here, first reflected light RL6A after passing through the beam splitter surface 214 may be output through the fourth side 212b of the second prism 210b.

The second reflected light RL5B may be reflected inward from the fourth side 212b of the second prism 210b. The second reflected light RL5B reflected from the fourth side 212b of the second prism 210b may be reflected by the beam splitter surface 214. In detail, the second reflected light RL5B may be reflected by the fourth side 214b of the second prism 210b. Here, second reflected light RL6B reflected by the beam splitter surface 214 may be output through the fourth side 212b of the second prism 210b.

In other words, the first reflected light RL5A is in a p-polarization state and may thus pass through the beam splitter surface 214. The second reflected light RL5B is in an s-polarization state and may thus be reflected from the second reflected light RL5B. Accordingly, the first reflected light RL6A after passing through the beam splitter surface 214 and the second reflected light RL6B after being reflected from the beam splitter surface 214 may all be output through the fourth side 212b of the second prism 210b.

As described above, when the optical head 200 includes the first phase retarder 250a, the second phase retarder 250b, and the polarizing prism 210, the optical head 200 may polarize illumination light or reflected light such that the first reflected light RL5A and the second reflected light RL5B may all be output to the photodetector 300 after being reflected or transmitted by the polarizing prism 210. In other words, light may be prevented from being output to the illuminator 110 through the first phase retarder 250a, the second phase retarder 250b, and the polarizing prism 210. According to an example embodiment, because all the illumination light L10 generated from the illuminator 110 is output to the photodetector 300, light loss may be decreased, and it may be possible to secure a sufficient amount of light to generate an image of an alignment mark. According to an example embodiment, because the loss of light returning to the illuminator 110 is prevented, the efficiency of the optical device 100 may be increased.

In addition, according to an example embodiment, because more light may be output to the photodetector 300 compared to optical devices according to the related art, the image contrast of alignment marks may be increased. Accordingly, bonding accuracy between the die D and the wafer W may be increased. When the loss of light returning to the illuminator 110 is prevented, heat generation may be prevented from occurring in the optical device 100, and the internal components of the optical device 100 may be prevented from being damaged.

The fourth side 212b of the second prism 210b may be used as an exit surface for the first reflected light RL6A and the second reflected light RL6B. Accordingly, the first reflected light RL6A and the second reflected light RL6B may be output in a fourth horizontal direction, which is orthogonal to the vertical direction (the Z direction), through the fourth side 212b of the second prism 210b. The first reflected light RL6A and the second reflected light RL6B may be output in the fourth horizontal direction such that the optical axis of each of the first reflected light RL6A and the second reflected light RL6B is orthogonal to the fourth side 212b of the second prism 210b. According to an example embodiment, when the first to third horizontal directions are not labelled or provided, the fourth horizontal direction may be referred to as the first horizontal direction. According to an example embodiment, when the first horizontal direction is labelled or provided and the second and third horizontal directions are not labelled or provided, the fourth horizontal direction may be called the second horizontal direction.

The first reflected light RL6A, which is output from the optical head 200 through the first right-angle prism 240a of the folding mirror unit 240, the first lens 230a, the first reflector 220a, and the polarizing prism 210, may have a third optical path. The second reflected light RL6B, which is output from the optical head 200 through the second right-angle prism 240b of the folding mirror unit 240, the second lens 230b, the second reflector 220b, and the polarizing prism 210, may have a fourth optical path. At this time, the length of the third optical path may be the same as the length of the fourth optical path.

The first reflected light RL6A and the second reflected light RL6B, which exit through the fourth side 212b of the second prism 210b, may be focused on the photodetector 300 through the tube lens 140. The photodetector 300 may obtain the image of the first alignment mark M1 from the first reflected light RL6A and the image of the second alignment mark M2 from the second reflected light RL6B. For example, the photodetector 300 may include a charge-coupled device (CCD) sensor.

The first reflected light RL6A and the second reflected light RL6B, which are detected by the photodetector 300, may respectively include image information of the first alignment mark M1 and image information of the second alignment mark M2. The relative position between the first alignment mark M1 and the second alignment mark M2 may be detected by using the image information.

As described above, the optical head 200 may include prisms and lenses in a symmetrical structure. The optical head 200 may respectively direct the first illumination light L2A and L3A and the second illumination light L2B and L3B, which propagate or travel on a horizontal plane, vertically downwards to the first alignment mark M1 of the wafer W and vertically upwards to the second alignment mark M2 of the die D, and the optical head 200 may output the first reflected light RL4A, RL5A, and RL6A reflected from the first alignment mark M1 and the second reflected light RL4B, RL5B, and RL6B reflected from the second alignment mark M2. The wafer W and the die D may be supported to face each other in the vertical direction (the Z direction).

Accordingly, the first illumination light L2A and L3A may have the same optical path as the first reflected light RL4A, RL5A, and RL6A, and the second illumination light L2B and L3B may have the same optical path as the second reflected light RL4B, RL5B, and RL6B. The optical head 200 may have a rigid body so as to be resistant to vibration.

According to an example embodiment, because the optical head 200 is relatively thin, the distance between the wafer W and the die D during alignment measurement may be decreased, and interference between a stage and an optical system may also be decreased.

Furthermore, images of both the first alignment mark M1 of the wafer W and the second alignment mark M2 of the die D may be obtained with one shot and observed at a high magnification, and the efficiency of illumination may be increased by separating illumination from an optical imaging system.

A method of bonding a die to a wafer by using the die bonding system described above is described below.

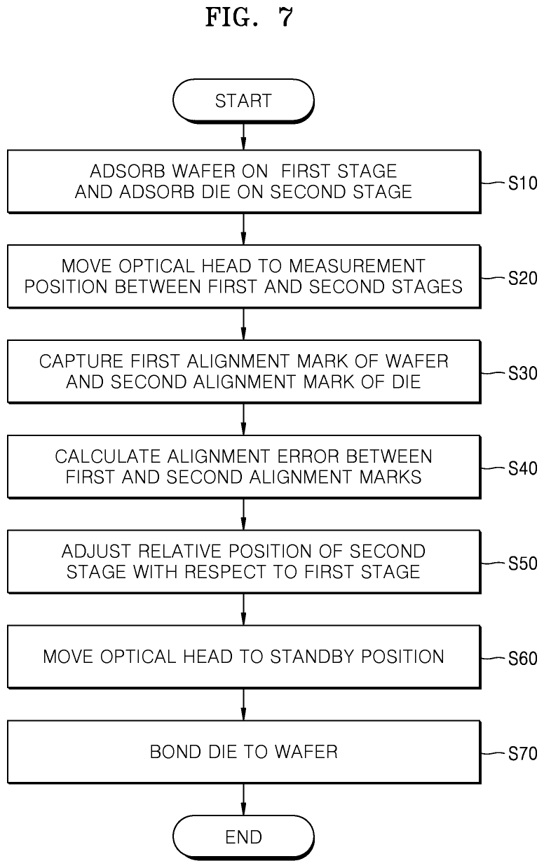

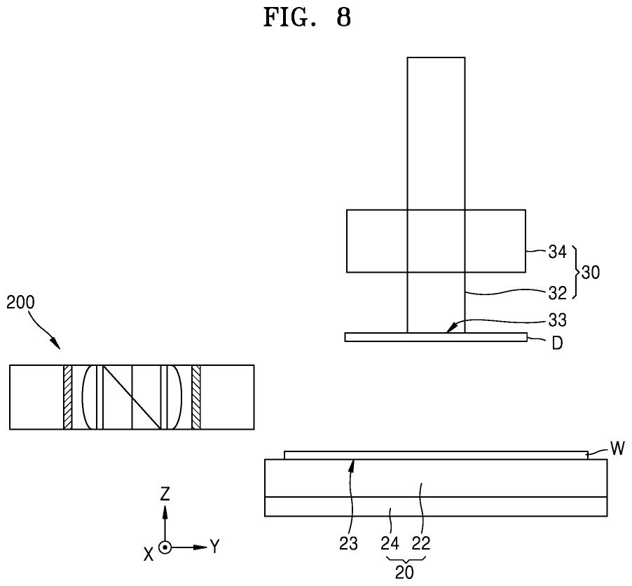

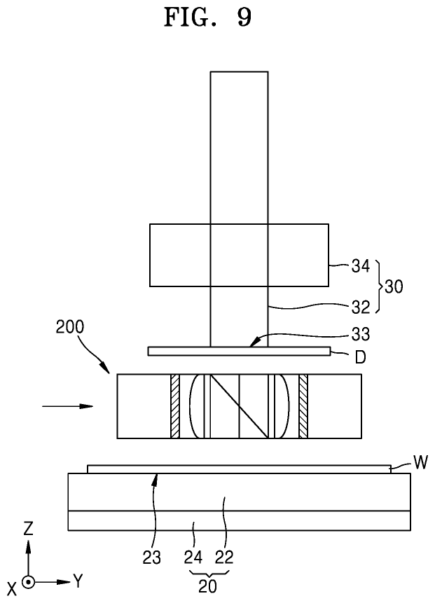

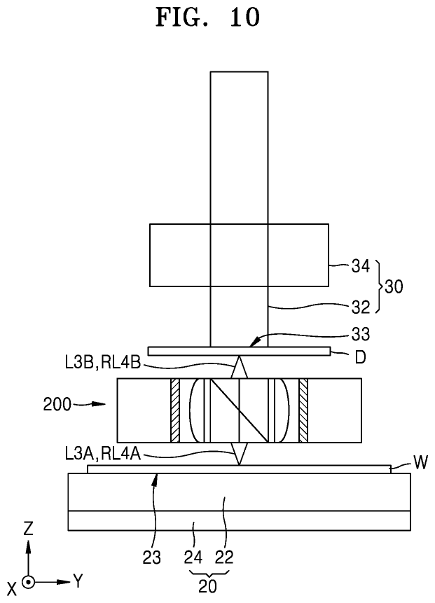

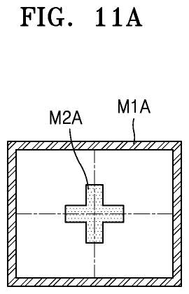

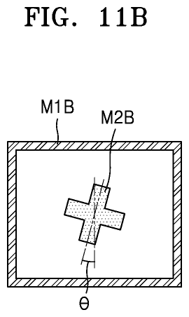

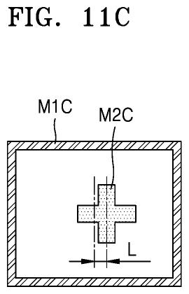

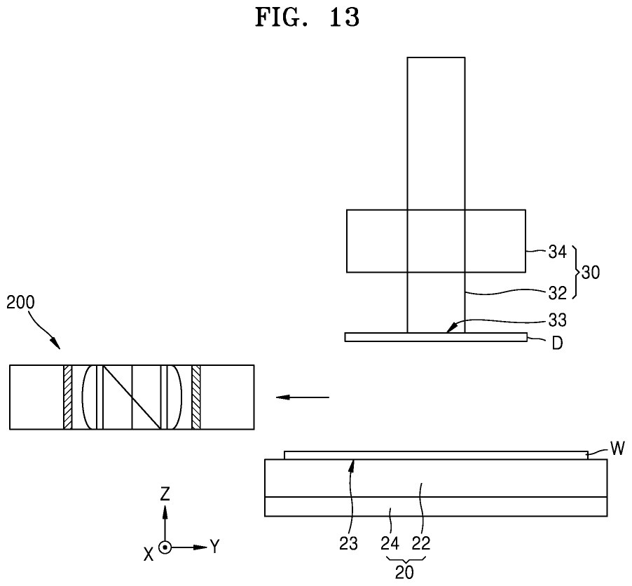

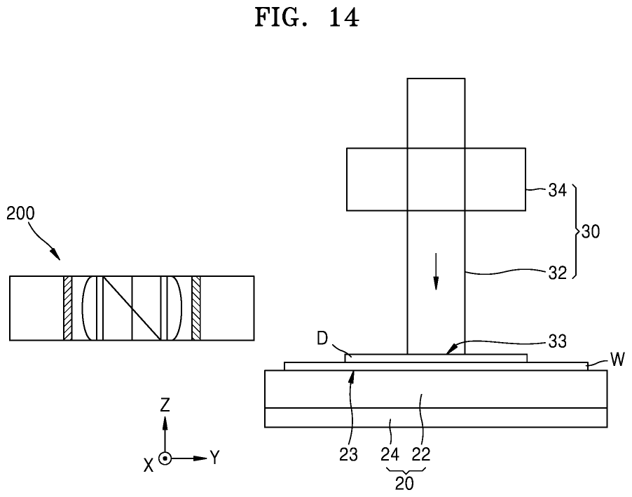

FIG. 7 is a flowchart of a die bonding method according to an example embodiment. FIGS. 8 to 10 and FIGS. 12 to 14 are cross-sectional views of stages in a die bonding method, according to an example embodiment. FIGS. 11A, 11B and 11C are diagrams showing images with respect to a first alignment mark and a second alignment mark, according to an example embodiment.

Referring to FIGS. 7 and 8, in operation S10, the wafer W may be adsorbed and fixed to the first stage 22 and the die D may be adsorbed and fixed to the second stage 32 of the die bonding system. According to an example embodiment, the wafer W and the die D may be simultaneously adsorbed and fixed to the first stage 22 and the second stage 32 respectively.

For example, the wafer W may be vacuum-adsorbed by decompression holes formed in the first stage 22. The die D individualized by a sawing process may be vacuum-adsorbed by a collet formed in the second stage 32. At this time, the optical head 200 of an optical device for an alignment check may be at a standby position outside the first and second stages 22 and 32.

Subsequently, alignment between the wafer W and the die D may be checked.

Referring to FIGS. 7, 9, and 10, in operation S20, the optical head 200 may be moved to a measurement position between the first and second stages 22 and 32, and in operation S30, the first alignment mark M1 formed on the wafer W and the second alignment mark M2 formed on the die D may be captured. According to an example embodiment, the first alignment mark M1 formed on the wafer W and the second alignment mark M2 formed on the die D may be simultaneously captured

In detail, the optical head 200 may be moved by the optical head driver 106 in a horizontal direction (e.g., along the X-Y plane) to a predetermined measurement position (e.g., the first image-capturing position) between the first and second alignment marks M1 and M2, which are spaced apart to face each other in the vertical direction (the Z direction).

Thereafter, the first alignment mark M1 and the second alignment mark M2 may be simultaneously captured by the optical head 200. According to an example embodiment, the optical head 200 may split incident illumination light into the first illumination light L2A and the second illumination light L2B and respectively radiate the first illumination light L2A and the second illumination light L2B to the first alignment mark M1 and the second alignment mark M2 and transmit the first reflected light RL4A from the first alignment mark M1 and the second reflected light RL4B from the second alignment mark M2 to the photodetector 300. The photodetector 300 may obtain the images of the first and second alignment marks M1 and M2 from the first reflected light RL6A and the second reflected light RL6B transmitted by the optical head 200.

After the first and second alignment marks M1 and M2 are captured at the first image-capturing position, the optical head 200 may be moved to the second image-capturing position, and the same alignment check may be performed. Subsequently, alignment between the wafer W and the die D may be performed based on a result of the image capturing.

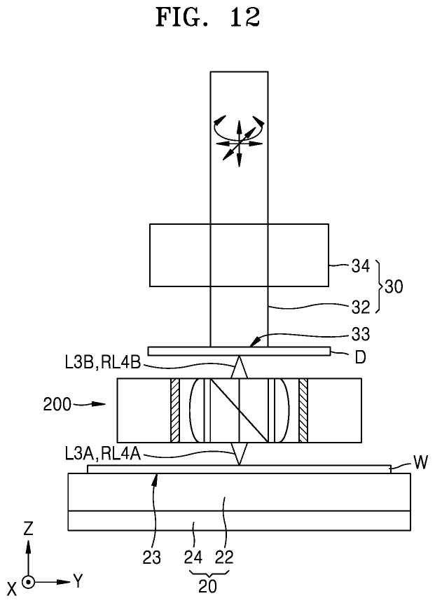

Referring to FIGS. 7 and 12, an alignment error between the first and second alignment marks M1 and M2 may be calculated in operation S40, and a relative position of the second stage 32 with respect to the first stage 22 may be adjusted to remove the alignment error in operation S50.

Referring to FIG. 11A and FIG. 12, it may be seen that a second alignment mark M2A is at the center of a first alignment mark M1A. In this case, the alignment error may be calculated as 0, and the controller 400 may not perform alignment of the first and second stages 22 and 32.

Referring to FIG. 11B and FIG. 12, it may be seen that a second alignment mark M2B is at the center of a first alignment mark M1B, but a center line of the first alignment mark M1B and a center line of the second alignment mark M2B form an angle θ. In this case, the controller 400 may control the bonding head driver 34 to rotate the second stage 32 by the angle θ to align the second stage 32 with the second stage 22.

Referring to FIG. 11C and FIG. 12, it may be seen that a center line of the second alignment mark M2C deviates by a length L from a center line of a first alignment mark M1C. In this case, the controller 400 may calculate the alignment error as the length L and control the bonding head driver 34 to horizontally move the second stage 32 by the length L such that the alignment error is removed.

In detail, the first reflected light RL6A and the second reflected light RL6B, which are detected by the photodetector 300, may respectively include image information of the first alignment mark M1 and image information of the second alignment mark M2. The relative position between the first and second alignment marks M1 and M2 may be detected by using the image information. The controller 400 may calculate an alignment error between the die D and the wafer W, based on the relative position between the first and second alignment marks M1 and M2. To remove the alignment error, the controller 400 may control the bonding head driver 34 to align the second stage 32 with the first stage 22.

Thereafter, the die D may be bonded to the wafer W.

Referring to FIGS. 7, 13, and 14, the optical head 200 may be moved to the standby position in operation S60, and the die D may be bonded to the wafer W in operation S70.

After the optical head 200 is moved by the optical head driver 106 to the standby position, the second stage 32 may descend to press the die D onto the wafer W. At this time, a heater may be provided in the second stage 32 to heat the die D and thermally compress the die D on the wafer W.

The die bonding system described above may be used to manufacture a semiconductor package including a logic device or a memory device For example, the semiconductor package may include a logic device, such as a central processor unit (CPU), a microprocessor unit (MPU), or an application processor (AP), a volatile memory device, such as a static random access memory (SRAM) device, a dynamic RAM (DRAM) device, or a high bandwidth memory (HBM) device, and a non-volatile memory device, such as a flash memory device, a phase-change RAM (PRAM) device, a magnetic RAM (MRAM) device, or a resistive RAM (RRAM) device.

While some embodiments of the disclosure have been particularly shown and described with reference to embodiments thereof, it will be understood that various changes in form and details may be made therein without departing from the spirit and scope of the following claims.

What is claimed is:

1. A die bonding system comprising:
an optical device comprising:
a light source configured to emit light;
a polarizing prism configured to polarize the light incident a first surface of the polarizing prism in a horizontal direction that is orthogonal to the first surface;
a first reflector and a second reflector, each of the first reflector and the second reflector being configured to reflect the light output from the polarizing prism;
a first lens configured to condense the light reflected by the first reflector; and
a second lens configured to condense the light reflected by the second reflector.

2. The die bonding system of claim 1, wherein the polarizing prism comprises:
a first prism, and
a second prism adjacent to the first prism, and
wherein the first prism and the second prism provide a splitter surface configured to split the light into first light and second light.

3. The die bonding system of claim 2, wherein the first light is reflected from the splitter surface, is totally reflected inside the first prism, and is output to the first reflector, and
wherein the second light passes through the splitter surface, is totally reflected inside the second prism, and is output to the second reflector.

4. The die bonding system of claim 1, wherein the polarizing prism is further configured to linearly polarize the light incident on the polarizing prism in the horizontal direction.

5. The optical device of claim 1, wherein the polarizing prism is further configured to allow p-polarization to pass through a splitter surface of the polarizing prism and s-polarization to be reflected by the splitter surface.

6. The die bonding system of claim 1, further comprising:
a first phase retarder adjacent to the first reflector, and
a second phase retarder adjacent to the second reflector,
wherein the light is incident on the first phase retarder and the second phase retarder.

7. The die bonding system of claim 6, wherein each of the first phase retarder and the second phase retarder is configured to circularly polarize the light.

8. The die bonding system of claim 1, further comprising:
a folding mirror unit configured to:
radiate the light from the first lens to a first alignment mark, and
radiate the light from the second lens to a second alignment mark,
wherein the first alignment mark is spaced apart from and faces the second alignment mark in a vertical direction that is orthogonal to the horizontal direction.

9. The die bonding system of claim 8, wherein the folding mirror unit comprises:
a first reflective surface configured to reflect first reflected light reflected from the first alignment mark, and
a second reflective surface configured to reflect second reflected light reflected from the second alignment mark, and
wherein the first reflected light and the second reflected light are output in opposite horizontal directions orthogonal to the vertical direction.

10. The die bonding system of claim 9, further comprising:
a photodetector configured to detect the first reflected light and the second reflected light, each of the first reflected light and the second reflected light being output from a second surface of the polarizing prism.

11. A die bonding system comprising:
a first stage having a first adsorbing surface, the first stage being configured to adsorb a wafer on the first adsorbing surface;
a second stage having a second adsorbing surface facing the first adsorbing surface in a vertical direction, the second stage being configured to adsorb a die on the second adsorbing surface;
a first driver configured to move at least one of the first stage and the second stage; and
an optical device configured to:
simultaneously capture a first alignment mark of the wafer and a second alignment mark of the die, and
detect information about a relative position between the first alignment mark and the second alignment mark,
wherein the optical device comprises:
a light source configured to emit light; and
a photodetector configured to detect reflected light generated when the light is reflected from the wafer and the die,
wherein the optical device is further configured to polarize the light and the reflected light, and
wherein the optical device is configured to be movable between the first stage and the second stage in a horizontal direction that is orthogonal to the vertical direction.

12. The die bonding system of claim 11, wherein the optical device further comprises:
a polarizing prism configured to linearly polarize the light incident on a first surface of the polarizing prism in the horizontal direction; and
a first phase retarder and a second phase retarder, each of the first phase retarder and the second phase retarder being configured to polarize and retard the light or the reflected light reflected from one of the first alignment mark and the second alignment mark.

13. The die bonding system of claim 12, wherein the reflected light comprises first reflected light and second reflected light,
wherein the first phase retarder is configured to p-polarize the first reflected light reflected from the first alignment mark as p-polarized first reflected light, and
wherein the second phase retarder is configured to s-polarize the second reflected light reflected from the second alignment mark as s-polarized second reflected light.

14. The die bonding system of claim 13, wherein the polarizing prism is further configured to transmit the p-polarized first reflected light and reflect the s-polarized second reflected light.

15. The die bonding system of claim 11, wherein first reflected light reflected from the first alignment mark propagates along a first optical path of the optical device,
wherein second reflected light reflected from the second alignment mark propagates along a second optical path of the optical device, and
wherein a length of the first optical path is equal to a length of the second optical path.

16. The die bonding system of claim 15, wherein the photodetector is further configured to obtain a first image of the first alignment mark from the first reflected light reflected and a second image of the second alignment mark from the second reflected light reflected.

17. The die bonding system of claim 11, wherein the optical device further comprises a second driver configured to move the optical device to a measurement position between the first stage and the second stage or a standby position outside the first stage and the second stage.

18. A die bonding system comprising:
a first stage having a first adsorbing surface, the first stage being configured to adsorb a wafer on the first adsorbing surface;
a second stage having a second adsorbing surface facing the first adsorbing surface in a vertical direction, the second stage being configured to adsorb a die on the second adsorbing surface;
a first driver configured to move at least one of the first stage and the second stage; and
an optical device configured to:
simultaneously capture a first alignment mark of the wafer and a second alignment mark of the die, and
detect information about a relative position between the first alignment mark and the second alignment mark,
wherein the optical device comprises:
a polarizing prism configured to split light into first light with s-polarization and second light with p-polarization, the light being incident on a first surface of the polarizing prism in a horizontal direction that is orthogonal to the vertical direction; and
a first phase retarder and a second phase retarder, each configured to polarize and retard the light or reflected light reflected from one of the first alignment mark and the second alignment mark, and
wherein the optical device is configured to be movable between the first stage and the second stage in the horizontal direction that is orthogonal to the vertical direction.

19. The die bonding system of claim 18, wherein the first driver is further configured to rotate or move at least one of the first stage and the second stage based on the information about the relative position.

20. The die bonding system of claim 18, further comprising:
a second driver configured to move the optical device to a measurement position between the first stage and the second stage or a standby position outside the first stage and the second stage,
wherein, after the at least one of the first stage and the second stage is moved by the first driver, the second driver is further configured to move the optical device from the measurement position to the standby position.
